(19) United States
(12) Patent Application Publication
(10) Pub. No.: US 2020/0050348 A1
(43) Pub. Date: Feb. 13, 2020

(54) TOUCH-TYPE INPUT DEVICE AND OPERATION DETECTION METHOD

(71) Applicants: Alpine Electronics, Inc., Tokyo (JP); Alps Alpine Co., Ltd., Ota-ku, Tokyo (JP)

(72) Inventors: Masanori YABUKI, Tokyo (JP); Masato YAMASHITA, Tokyo (JP)

(21) Appl. No.: 16/343,618

(22) PCT Filed: Jul. 18, 2017
(86) PCT No.: PCT/JP2017/025895

§ 371 Date: Apr. 19, 2019

(30) Foreign Application Priority Data
Nov. 4, 2016 (JP) 2016-216450

(51) Int. Cl. G06F 3/0484; G06F 3/0488; H03K 17/96; G06F 3/01

(52) U.S. Cl. CPC G06F 3/04847; G06F 3/016; H03K 17/96; G06F 3/0488

(57) ABSTRACT

A first operation region 11 for providing a first tactile sensation and second operation regions 12__{U} and 12__{D} for providing a second tactile sensation are arranged adjacent to each other. when a detection unit 20 detects a slide operation from the first operation region 11 to the second operation region 12_{U} or 12_{D}, an operation control unit 30 outputs a second operation signal different from a first operation signal output depending on a movement distance of the slide operation on the first operation region 11. Therefore, the second operation signal is output when the degree of operation is not sufficient even by performing a slide operation within the first operation region 11, and the movement of the finger stops at a place where a change from the first tactile sensation to the second tactile sensation occurs. As a result, it is possible to allow a user to perform an operation of a degree of operation desired by the user without performing the slide operation several times.

### TECHNICAL FIELD

The present invention relates to a touch-type input device and an operation detection method, and is particularly suitable for use in a touch-type input device having a configuration that provides a tactile feedback to an operator.

### BACKGROUND ART

In general, a vehicle is mounted with various electronic devices such as an audio device, an air conditioner, and a navigation device. In addition, a touch-type input device for operating such electronic devices is provided on a console, a steering wheel, or the like. When an operation for such an electronic device is performed during driving, it is desirable to perform the operation without moving a line of sight on the touch-type input device. For this reason, a touch-type input device is provided, in which unevenness is provided on a surface of the operation surface in order to provide a tactile feedback to a user at the time of the operation, and a sensor is disposed inside the operation surface.

FIG. 11 is a diagram illustrating an exemplary configuration of the touch-type input device of the related art, in which unevenness is provided on the operation surface. In the touch-type input device of FIG. 11, a plurality of protrusions 101 are provided intermittently on the surface of the console or the like so that a tactile feedback is obtained when a user operates. A sensor 102 is provided inside the console facing the position where the protrusions 101 are provided. In the touch-type input device of FIG. 11, an operation for an audio volume, song selection, an air-conditioning level or temperature, map enlargement/reduction of a navigation device, or the like can be performed by making a slide operation (trace operation) on the operation surface provided with the protrusions 101.

Note that, a touch-type input device provided with unevenness on the operation surface is also known in the art in addition to the configuration of FIG. 11 (for example, see Patent Documents 1 to 3). In the input device described in Patent Document 1, various attributes are set on vertical and horizontal axes on a touch sensor panel, and protrusions are formed along an origin position, a vertical axis direction, and a horizontal axis direction on the touch sensor panel. As a result, a player playing an electronic musical instrument can recognize a position on the touch sensor panel merely by a tactile sensation of a finger without moving the line of sight, and can adjust a musical tone output to an arbitrary level by an operation such as pressing or sliding on the touch sensor panel.

In the operation device described in Patent Document 2, when a user moves a fingertip by touching protrusions of the operation device, a capacitance type sensor detects this motion so that a selection frame for selecting a menu moves vertically and horizontally. In addition, the menu is selected as the selection frame reaches the target menu. In this manner, a desired menu can be selected from a plurality of menus merely by moving the finger while touching the protrusions without pressing an operation key.

The touch-type input device described in Patent Document 3 includes a surface plate having a plurality of protrusions on an operation surface and an area changing as the protrusions are directed to a predetermined direction, and a sensor arranged on a back side of the surface plate for detecting a position on the operation surface touched by a user's finger. When a user traces the operation surface of the surface plate with a finger, the user can tactually perceive the position of the finger on the operation surface on the basis of a change of the size of the protrusion.

Patent Document 1: JP-A-10-240250

Patent Document 2: JP-A-2009-181407

Patent Document 3: JP-A-2013-114651

### DISCLOSURE OF THE INVENTION

Even using a touch-type input device provided with unevenness on the operation surface, when a user tries to perform a blind touch without moving the line of sight to the touch-type input device, it is difficult to say that the user can touch a start point of the operation surface from the beginning. When a user initially touches a middle position between the start point and the end point on the operation surface, a degree of operation desired by the user is not satisfied in many cases even by performing the slide operation from that position. In this case, it is necessary to perform the slide operation from the middle position to the end point once, and then perform the slide operation again by moving the finger to the start point of the operation surface, which is cumbersome disadvantageously.

Note that, as one of methods for addressing such a problem, it is considered that the amount of the slide operation may increase as much as possible by increasing the area of the operation surface. However, this may increase the size of the operation surface or the sensor disadvantageously.

The present invention has been made to address such a problem, and an object thereof is to provide a touch-type input device having unevenness on an operation surface and capable of allowing a user to perform an operation of a desired degree of operation without performing the slide operation several times.

In order to address the aforementioned problems, there is provided a touch-type input device including: an operation unit having a first operation region for providing a first tactile sensation and a second operation region for providing a second tactile sensation different from the first tactile sensation, the first and second operation regions being disposed adjacent to each other; a detection unit that detects a touch position of a pointer on the first or second operation region; and an operation control unit that outputs an operation signal depending on an operation state. The operation control unit outputs a first operation signal of a degree of operation corresponding to a movement distance of the touch position when the detection unit detects a slide operation performed by changing the touch position within the first operation region. In addition, the operation control unit outputs a second operation signal different from the first operation signal when the detection unit detects the slide operation from the first operation region to the second operation region.

According to the present invention configured as described above, when a user makes a blind touch to the operation unit with a pointer such as a finger, a touch position is placed in a middle position between a start point and an end point of the first operation region and in a case where a degree of operation does not satisfy a degree of operation desired by the user even by making a slide operation from the middle position within the first operation region, a second operation signal is output in response to an operation to the second operation region, where the second tactile sensation is obtained, by continuously performing the slide operation by moving the pointer to a place where a change from the first tactile sensation to the second tactile sensation occurs. As a result, it is possible to perform an operation of a degree of operation desired by a user without performing the slide operation several times with a blind touch.

### BRIEF DESCRIPTION OF THE DRAWINGS

FIG. 1 is a diagram illustrating an exemplary configuration of a touch-type input device according to an embodiment.

FIG. 2 is a diagram illustrating an exemplary configuration of a detection unit according to an embodiment.

FIG. 3 is a diagram illustrating a state in which a slide operation is performed with a finger in a first direction.

FIG. 4 is a diagram illustrating a state in which a slide operation is performed with a finger in a second direction.

FIG. 5 is a flowchart illustrating an exemplary operation of the entire touch-type input device according to an embodiment.

FIG. 6 is a flowchart illustrating an exemplary operation of step S3 in FIG. 5.

FIG. 7 is a flowchart illustrating an exemplary operation of step S4 in FIG. 5.

FIG. 8 is a flowchart illustrating another exemplary operation of the touch-type input device according to an embodiment.

FIG. 9 is a diagram illustrating another exemplary configuration of an operation unit according to an embodiment.

FIG. 10 is a diagram illustrating another exemplary configuration of the operation unit according to an embodiment.

FIG. 11 is a diagram illustrating an exemplary configuration of a touch-type input device of the related art, in which unevenness is provided on the operation surface.

### BEST MODE FOR CARRYING OUT THE INVENTION

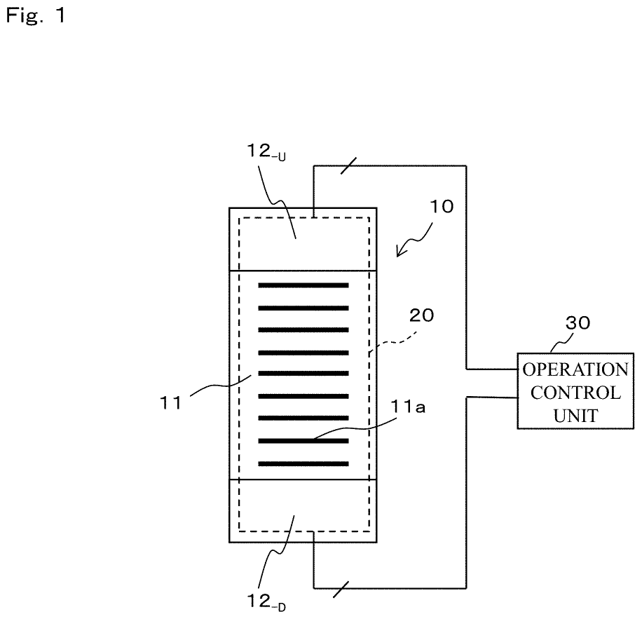

An embodiment of the present invention will now be described on the basis of the accompanying drawings. FIG. 1 is a diagram illustrating an exemplary configuration of a touch-type input device according to this embodiment. As illustrated in FIG. 1, the touch-type input device according to this embodiment includes an operation unit 10, a detection unit 20, and an operation control unit 30.

The operation unit 10 and the detection unit 20 are arranged in an interior part such as a vehicle console, a steering wheel, a dashboard, or a door panel. The operation unit 10 is provided on a surface of the interior part formed of synthetic resin, genuine leather, synthetic leather, or the like so that a user can operate by touching a finger. The detection unit 20 is provided at a position facing the operation unit 10 on the back side of the interior part or within the thickness of the interior, so as to detect a user's operation on the operation unit 10. The operation control unit 30 is a controller connected to the detection unit 20 through wiring.

As illustrated in FIG. 1, the operation unit 10 according to this embodiment has a first operation region 11 for providing a first tactile sensation and second operation regions 12_{U} and 12__{D} for providing a second tactile sensation different from the first tactile sensation, and these are arranged adjacent to each other. That is, one of the second operation region 12__{U} is arranged adjacent to one end of the first operation region 11, and the other second operation region 12__{D} is arranged adjacent to the other end of the first operation region 11. The first operation region 11 has a length by which the finger can slide in a vertical direction (up/down direction in the drawings). Meanwhile, it is sufficient that the second operation regions 12__{U} and 12__{D} are sized such that a finger can make contact without a movement.

The first operation region 11 has a plurality of bar-shaped protrusions 11a formed intermittently on its surface to provide unevenness. As a result, when a user touches and operates a finger on the first operation region 11, a first tactile sensation is provided, by which the user feels that he/she touches an uneven surface. In comparison, the second operation regions 12__{U} and 12__{D} have flat surfaces. As a result, when a user touches and operates a finger on the second operation region 12__{U} or 12__{D}, a second tactile sensation by which the user feels that he/she touches a flat surface is provided.

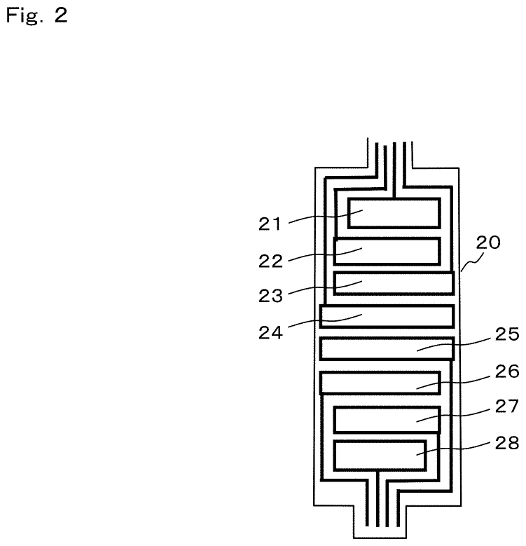

The detection unit 20 detects a touch position of a pointer such as a user's finger on the first operation region 11 or the second operation region 12__{U} or 12__{D}. The detection unit 20 can include a sensor known in the art, such as a capacitance type sensor or a pressure sensitive type sensor. Note that, a specific configuration of the detection unit 20 will be described below with reference to FIG. 2.

By making a slide operation (trace operation) on the operation unit 10, a user can perform operations for an audio volume control, song selection, an air volume or temperature of an air conditioner, map enlargement/reduction of a navigation device, opening/closing of a widow, or the like. In the first operation region 11, the detection unit 20 detects a change of the touch position caused by the slide operation as relative position information. In addition, in the second operation regions 12__{U} and 12__{D}, the detection unit 20 detects a touch operation.

when the detection unit 20 detects a slide operation in which the touch position changes within the first operation region 11, the operation control unit 30 outputs a first operation signal of a degree of operation corresponding to a movement distance of the touch position. In addition, when the detection unit 20 detects a slide operation from the first operation region 11 to the second operation region 12_{U} or 12_{D}, the operation control unit 30 outputs a second operation signal of a degree of operation corresponding to a period of time during which the touch position stops at the second operation region 12__{U} or 12__{D}.

For example, when an audio volume is controlled by a slide operation, an audio device (not illustrated) increases or decreases an audio volume depending on the degree of operation on the basis of an operation signal supplied from the operation control unit 30 (the first or second operation signal, hereinafter, simply referred to as an “operation signal” unless distinguished otherwise). In addition, when a setting temperature of the air conditioner is controlled by a slide operation, the air conditioner (not illustrated) increases or decreases the setting temperature depending on the degree of operation on the basis of the operation signal supplied from the operation control unit 30.

FIG. 2 is a diagram illustrating an exemplary configuration of the detection unit 20 according to this embodiment. As illustrated in FIG. 2, the detection unit 20 according to this embodiment has a plurality of sensor patterns 21 to 28 separately juxtaposed in a first direction (vertical direction) in which the first operation region 11 and the second operation regions 12_{U} and 12_{D} are adjacent to each other. Individual sensor patterns 21 to 28 have certain lengths in a second direction (horizontal direction) perpendicular to the first direction. Note that, the sensor patterns 21 and 28 face the second operation regions 12__{U} and 12__{D}, and the sensor patterns 22 to 27 face the first operation region 11.

In such a configuration of the sensor patterns 21 to 28, positions of the sensor patterns 21 to 28 for detecting a touch change while a finger slides along the first direction. As a result, the detection unit 20 detects a change of the touch position in the first direction as a slide operation. Meanwhile, the positions of the sensor patterns 21 to 28 for detecting a touch do not change even by sliding a finger in the second direction. For this reason, the detection unit 20 does not detect a change of the touch position in the second direction.

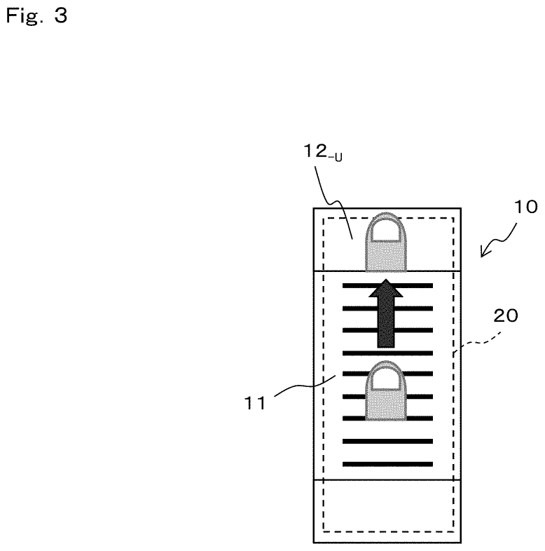

FIG. 3 is a diagram illustrating a state in which a slide operation is performed with a finger in the first direction. In the example of FIG. 3, a finger initially touches an arbitrary position in the first operation region 11, and then makes a slide operation upward in the drawing to be moved to the second operation region 12__{U}. Then, the finger stops for a while when touching the second operation region 12__{U}.

In this case, while the finger makes a slide operation within the first operation region 11, a first operation signal of a degree of operation corresponding to a movement distance of the touch position from the initial touch position is output from the operation control unit 30. For example, when an audio volume is controlled by the slide operation, the volume gradually increases while the slide operation is performed within the first operation region 11.

While the slide operation is performed within the first operation region 11, a user is provided with a first tactile sensation by which the user feels that there is unevenness. Meanwhile, there is no unevenness within the second operation region 12__{U} adjacent to the first operation region 11, and a user is provided with a second tactile sensation by which the user feels that he/she touches a flat surface. Therefore, when a finger is slid to the second operation region 12_{U} over the first operation region 11, the user can clearly recognize that the touch area changes without visually seeing it.

Here, when the degree of operation desired by the user is not satisfied, that is, the volume does not reach a desired level even when the slide operation is performed from the initial finger touch position within the first operation region 11 to the upper end of the first operation region 11, the finger may be continuously slid to the second region 12__{U} and may remain in touch with the second operation region 12__{U}. While the finger touches the second operation region 12__{U}, the second operation signal of the degree of operation corresponding to the touching time is output from the operation control unit 30 so as to continuously increase the volume. In addition, when the desired volume is reached, the user may separate the finger from the second operation region 12__{U}.

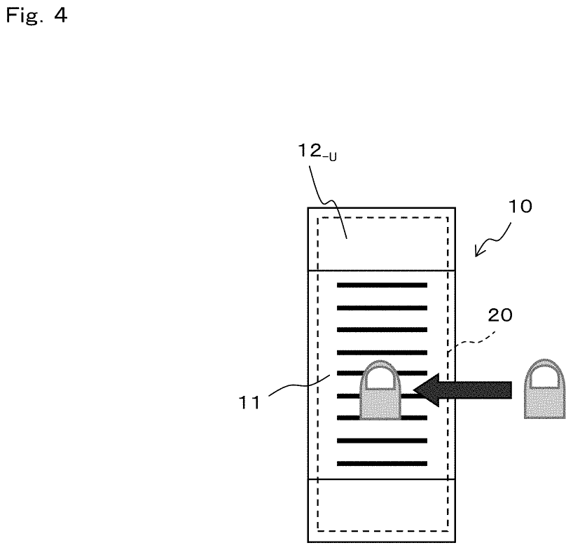

FIG. 4 is a diagram illustrating a state in which a slide operation is performed with a finger in the second direction. In the example of FIG. 4, the finger initially touches a position outside the operation unit 10 and then touches the first operation region 11 by moving to the left in the drawing. When a user tries to operate the operation unit 10 with a blind touch during driving, it is difficult to say that the user touches the first operation region 11 from the beginning. In this case, the user searches for the first operation region 11 by appropriately moving the finger.

That is, when a user initially touches a position outside the operation unit 10, it is difficult to obtain the first tactile sensation. Therefore, the user can clearly recognize that the first operation region 11 is not touched. For this reason, in order to search for the first operation region 11, the user moves the finger vertically or horizontally. FIG. 4 illustrates a state in which the first operation region 11 is searched by moving the finger horizontally. In this case, the detection unit 20 detects a change of the touch position in the horizontal direction (second direction), but an intensity of the detected signal does not change, so that this is not detected as a slide operation. Therefore, the first operation signal is not output from the operation control unit 30, and it is possible to prevent a failure such as a change of the audio volume contrary to a user's intention.

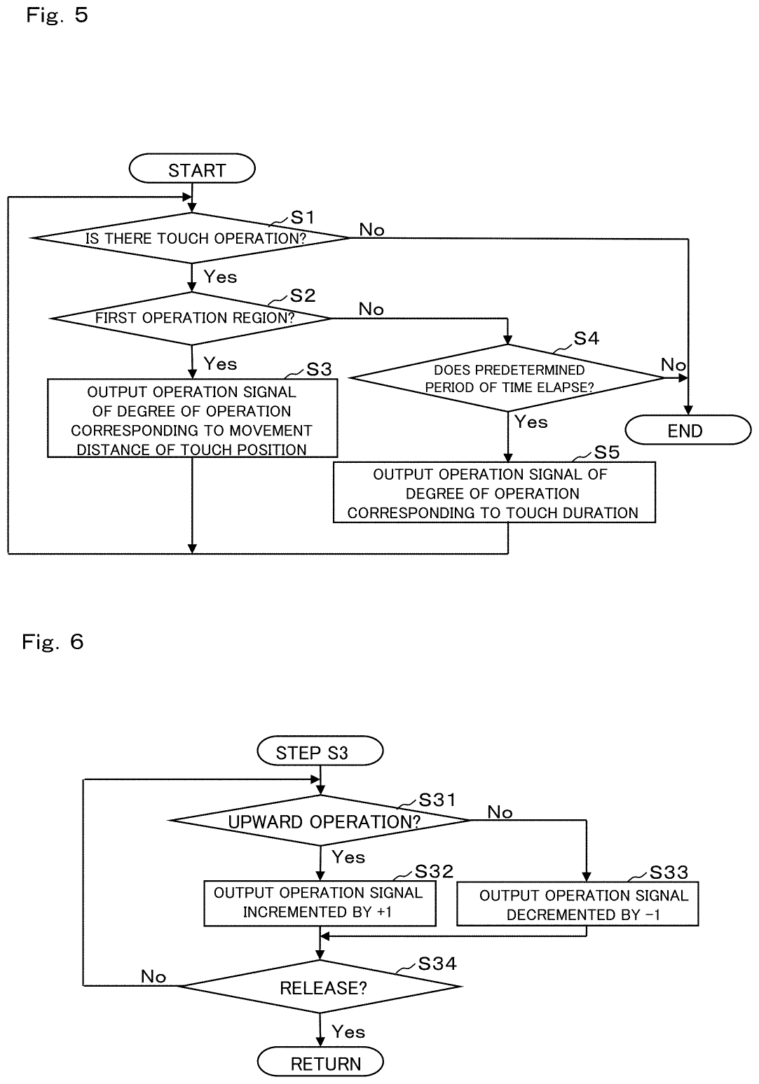

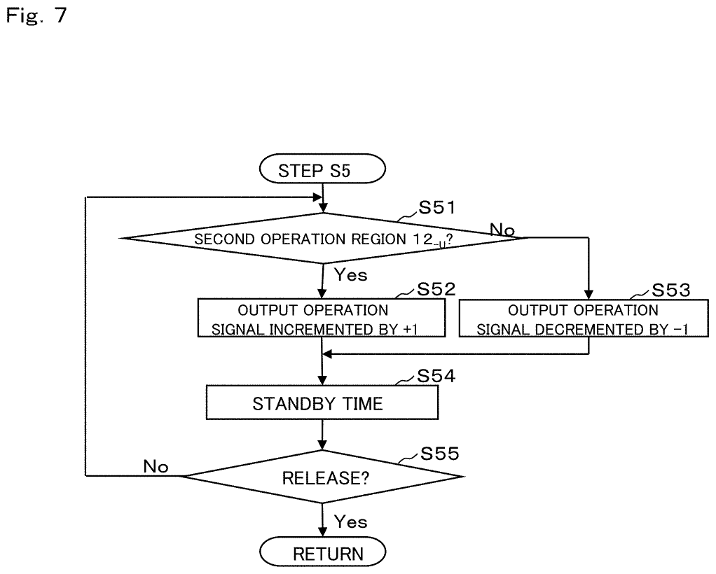

FIGS. 5 to 7 are flowcharts illustrating exemplary operations of the touch-type input device according to this embodiment configured as described above. FIG. 5 is a flowchart illustrating an exemplary operation of the entire touch-type input device. FIG. 6 is a flowchart illustrating an exemplary operation of step S3 in FIG. 5. FIG. 7 is a flowchart illustrating an exemplary operation of step S5 in FIG. 5.

In FIG. 5, first, the detection unit 20 determines whether or not there is a touch operation on the operation unit 10 (for the first operation region 11 or the second operation region 12__{U} or 12__{D}) (step S1). If there is no touch operation, the processing of the flowchart of FIG. 5 is terminated. Meanwhile, if a touch operation is detected by the detection unit 20, the operation control unit 30 determines whether or not the touch operation is performed on the first operation region 11 (step S2).

Here, if it is determined that the touch operation is performed on the first operation region 11, that is, if a change of the touch position detected by the detection unit 20 is performed within the first operation region 11, the operation control unit 30 outputs a first operation signal of a degree of operation corresponding to the movement distance of the touch position (step S3).

Meanwhile, if it is determined that the touch operation is not performed on the first operation region 11, that is, if the touch position detected by the detection unit 20 changes from the first operation region 11 to the second operation region 12__{U} or 12__{D}, the operation control unit 30 determines whether or not the touch operation on the second operation region 12__{U} or 12__{D} is continuously performed for a predetermined period of time (for example, arbitrary time such as 1 to 2 seconds) (step S4).

Here, when the touch operation on the second operation region 12_{U} or 12_{D} is terminated without continuing for a predetermined period of time, the processing of the flowchart of FIG. 5 is terminated. Meanwhile, if the touch operation on the second operation region 12__{U} or 12__{D} continues for the predetermined period of time, the operation control unit 30 outputs a second operation signal of a degree of operation corresponding to a period of time during which the touch position stops at the second operation region 12__{U} or 12__{D} (step S5).

Note that, in the case of the flowchart of FIG. 5, even when a user initially touches the second operation region 12__{U} or 12__{D} from the beginning, if the touch operation continues for a predetermined period of time, the operation control unit 30 outputs the second operation signal of the degree of operation corresponding to the period of time during which the touch position stops at the second operation region 12__{U} or 12__{D}. However, even when a user accidentally touches the second operation region 12__{U} or 12__{D} with a blind touch, the user is difficult to discriminate whether the touched position is placed inside the second operation region 12__{U} or 12__{D} or outside the operation unit 10 on the basis of the tactile sensation. Therefore, when the user touches the second operation region 12__{U} or 12__{D} from the beginning, it is difficult to say that the user continuously performs the touch operation at that position for a predetermined period of time or longer.

As a result, when a user touches the second operation region 12__{U} or 12__{D} from the beginning, the second operation signal is not substantially output from the operation control unit 30. In addition, the second operation signal of the degree of operation corresponding to the period of time during which the touch position stops at the second operation region 12__{U} or 12__{D} is output only when the touch position changes from the first operation region 11 to the second operation region 12__{U} or 12__{D}.

In FIG. 6, the operation control unit 30 determines whether or not the touch position detected by the detection unit 20 within the first operation region 11 changes upward (toward the second operation region 12__{U}) (step S31). If the touch position changes upward, the operation control unit 30 outputs the first operation signal for incrementing in a positive direction (step S32). As a result, for example, an audio volume increases by one level.

Meanwhile, if the touch position changes downward (toward the second operation region 12__{D}), the operation control unit 30 outputs a first operation signal for decrementing in a negative direction (step S33). As a result, for example, the audio volume decreases by one level. After the processing of step S32 or S33, the detection unit 20 determines whether or not the finger is separated from the first operation region 11 (including a case where the finger moves to the second operation region 12__{U} or 12__{D}) (step S34).

Here, if the finger is not separated from the first operation region 11, the processing returns to step S31, and the processing of step S3 in FIG. 5 is continuously performed. Meanwhile, if the finger is separated from the first operation region 11, the processing returns. In this case, the processing of step S3 in FIG. 5 is omitted, and the determination of step S1 is performed again. When the user performs a slide operation from the first operation region 11 to the second operation region 12__{U} or 12__{D}, a touch operation is detected again in step S1, and the processing advances from step S2 to step S4.

In FIG. 7 illustrating the processing of step S5, the operation control unit 30 determines whether or not the touch position detected by the detection unit 20 is placed in the second operation region 12__{U} (step S51). If the touch position is placed in the second operation region 12__{U}, the operation control unit 30 outputs a second operation signal for incrementing in a positive direction (step S52). As a result, for example, an audio volume increases by one level.

Meanwhile, if the touch position is placed in the second operation region 12__{D}, the operation control unit 30 outputs a second operation signal for decrementing in a negative direction (step S53). As a result, for example, the audio volume decreases by one level. After the processing of step S52 or S53, the detection unit 20 determines whether or not the finger is separated from the second operation region 12__{U} or 12__{D} after a predetermined standby time (step S54) (including a case where the finger moves to the first operation region 11) (step S55).

Here, if the finger is not separated from the second operation region 12__{U} or 12__{D}, the processing returns to step S51, and the processing of step S5 in FIG. 5 is continuously performed. Otherwise, if the finger is separated from the second operation region 12_{U} or 12_{D}, the processing returns, processing of step S5 in FIG. 5 is omitted, and the determination of step S1 is performed again.

As described above in details, in the touch-type input device according to this embodiment, the first operation region 11 for providing the first tactile sensation and the second operation region 12__{U} or 12__{D} for providing the second tactile sensation different from the first tactile sensation are arranged adjacent to each other. In addition, when a slide operation from the first operation region 11 to the second operation region 12__{U} or 12__{D} is detected, the second operation signal of the degree of operation corresponding to the period of time during which the touch position stops at the second operation region 12_{U} or 12_{D} is output.

According to this embodiment configured as described above, when a user's finger position making a blind touch with the operation unit 10 is in a middle position between one end and the other end of the first operation region 11, and the touch does not satisfy a degree of operation desired by the user even by performing a slide operation from the middle position within the first operation region 11, the second operation signal of the degree of operation corresponding to the period of time during which the touch position stops at the second operation region 12_{U} or 12_{D}, where the second tactile sensation is obtained, is output by continuously performing the slide operation and stopping the movement of the finger at a place where a change from the first tactile sensation to the second tactile sensation occurs. As a result, it is possible to perform an operation with a degree of operation desired by a user without performing the slide operation several times with a blind touch.

In addition, according to this embodiment, it is possible to obtain a degree of operation desired by a user through a single slide operation from the first operation region 11 to the second operation region 12__{U} or 12__{D} and a subsequent touch operation at the second operation region 12__{U} or 12__{D}. As a result, it is not necessary to lengthen any one of the first operation region 11 and the second operation regions 12__{U} and 12__{D}. In addition, it is not necessary to increase the size of the operation unit 10 advantageously.

Note that, in the aforementioned embodiment, an example has been described, in which, even when a user touches the second operation region 12__{U} or 12__{D} from the beginning, a state that the touch operation continues for a predetermined period of time is detected, and the second operation signal of the degree of operation corresponding to the period of time during which the touch position stops at the second operation region 12__{U} or 12__{D} is then output. However, the present invention is not limited thereto. That is, when the detection unit 20 initially detects a touch on the second operation region 12__{U} or 12__{D}, the operation control unit 30 may perform control such that the second operation signal is not output even when the touch position stops at the second operation region 12__{U} or 12__{D}.

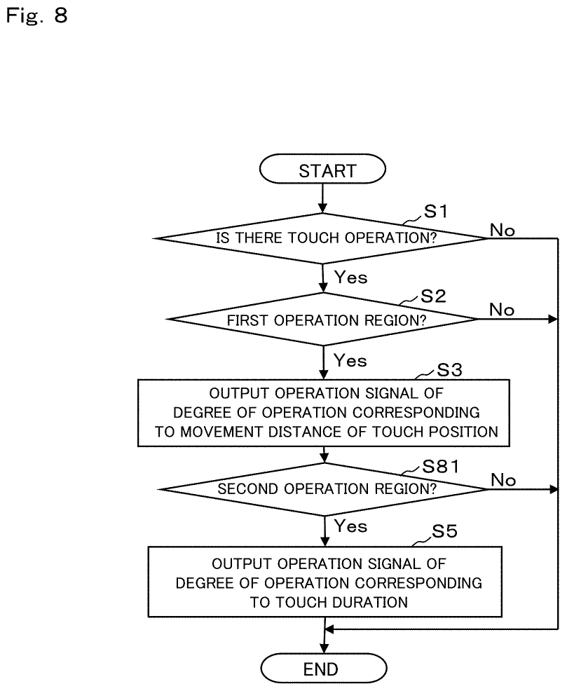

FIG. 8 is a flowchart illustrating an exemplary operation of the touch-type input device in this case. In FIG. 8, like reference numerals denote like processing as step numerals illustrated in FIG. 5, and they will not be described repeatedly. Details of the processing of steps S3 and S5 are similar to those of FIGS. 6 and 7, respectively.

In the flowchart of FIG. 8, if the processing returns in step S3 (step S34 in FIG. 6), it is determined whether or not the finger slides to the second operation region 12__{U} or 12__{D} (step S81). If the finger does not slide, that means that the finger is simply separated from the first operation region 11. Therefore, the processing is terminated. Meanwhile, if it is determined that the finger slides to the second operation region 12__{U} or 12__{D}, the processing of step S5 is executed continuously.

In addition, in step S2 in FIG. 8, if it is determined that the initial touch operation is not for the first operation region 11, that is, if it is determined that a touch operation on the second operation region 12__{U} or 12__{D} is initially performed, the processing of the flowchart of FIG. 8 is terminated without performing the processing of steps S3 and S5.

As described above, the operation control unit 30 determines which one of the first operation region 11 or the second operation region 12__{U} or 12__{D} the touch position initially detected by the detection unit 20 is placed. If it is determined that the initial touch position is placed in the second operation region 12__{U} or 12__{D}, the operation control unit 30 performs control such that the second operation signal is not output even when the touch position stops at the second operation region 12__{U} or 12__{D}.

Even when a user accidentally touches the second operation region 12__{U} or 12__{D} at the time of a blind touch, the user is difficult to discriminate whether the touched position is placed inside the second operation region 12__{U} or 12__{D} or outside the operation unit 10 on the basis of a tactile sensation. Therefore, if the second operation signal is not output when a touch on the second operation region 12__{U} or 12__{D} is initially detected, it is possible to prevent the second operation signal from being output contrary to a user's intention.

Note that, the second tactile sensation obtained by touching the second operation region 12__{U} or 12__{D} may be set to be different from a third tactile sensation obtained by touching a region outside the operation unit 10. In this case, it is preferable to set different tactile sensations between the upper second operation region 12__{U} and the lower second operation region 12__{D}. As a result, even when a user touches the second operation region 12__{U} or 12__{D} from the beginning, the user can recognize it. Therefore, a second operation signal corresponding to a touch duration may be output in a case where the user initially touches the second operation region 12__{U} or 12__{D}, and then continuously touches it.

In addition, in the aforementioned embodiment, an example has been described, in which the operation control unit 30 outputs an operation signal of a degree of operation corresponding to a period of time during which the touch position stops at the second operation region 12__{U} or 12__{D} as the second operation signal. However, the present invention is not limited thereto. For example, the second operation regions 12__{U} and 12__{D} are sized such that a finger can move by a distance shorter than the first operation region 11, and the sensor patterns 21 and 28 facing the second operation regions 12__{U} and 12__{D}, respectively, are divided into a plurality of segments in the first direction. In addition, the operation control unit 30 may output, as the second operation signal, an operation signal of a degree of operation that corresponds to the movement distance of the touch position in the second operation region 12__{U} or 12__{D} and is larger than that corresponding to the movement distance of the touch position within the first operation region 11.

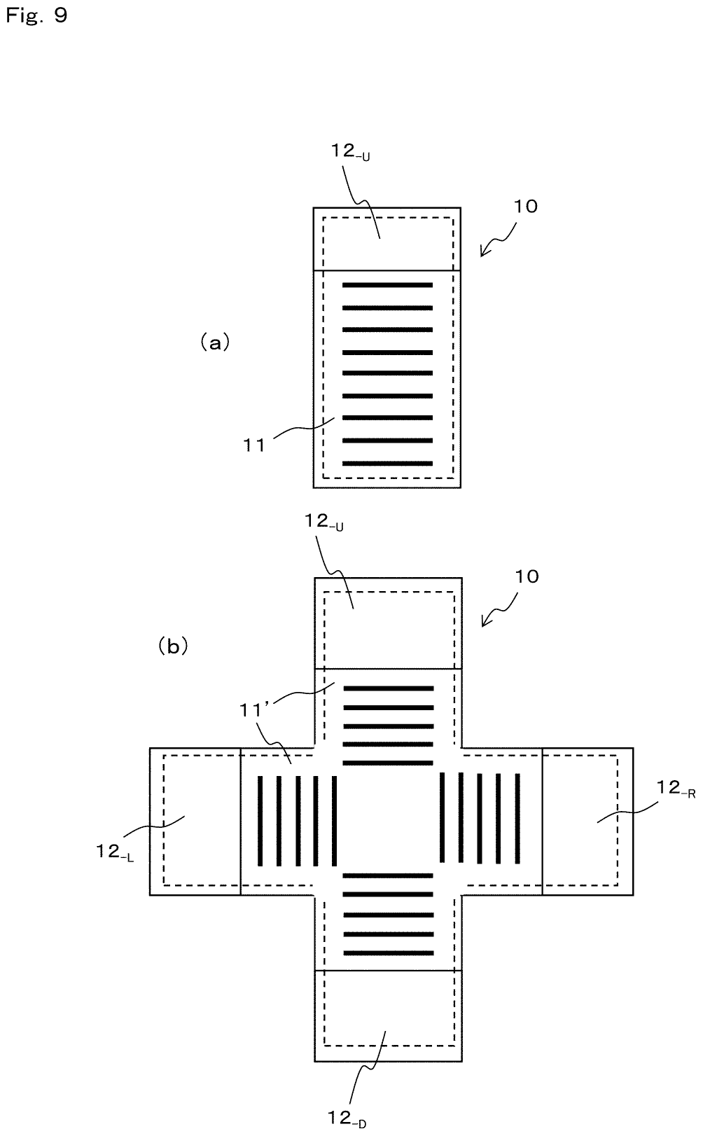

In the aforementioned embodiment, an example has been described, in which the second operation regions 12__{U} and 12__{D} are arranged adjacent to both sides of the first operation region 11. However, the present invention is not limited thereto. For example, as illustrated in FIG. 9(a), the second operation region 12__{U} may be arranged adjacent to only one side of the first operation region 11. Naturally, the second operation region 12__{D} may be arranged adjacent to only the other side of the first operation region 11. In addition, as illustrated in FIG. 9(b), the first operation region 11′ may be formed in a cross shape, and the second operation regions 12__{U}, 12__{D}, 12__{L}, and 12__{R} may be arranged adjacently in four directions.

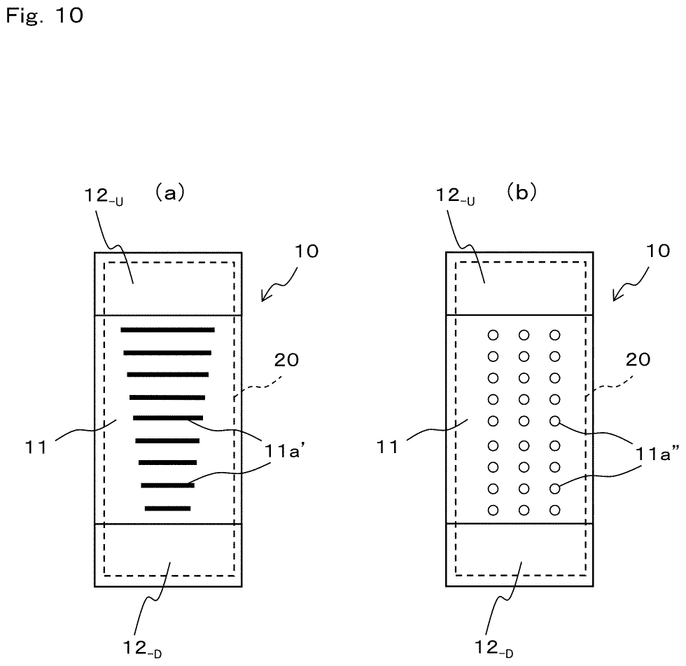

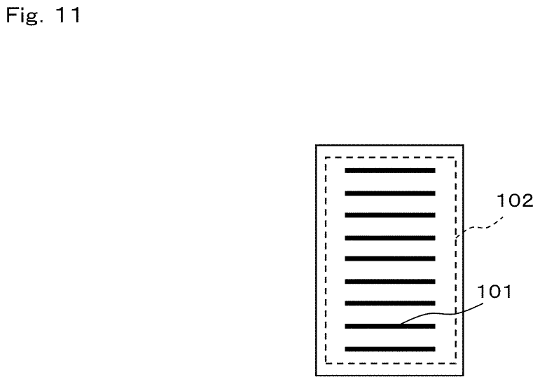

In the aforementioned embodiment, a configuration has been described, in which bar-shaped protrusions 11a having the same length are intermittently formed on the surface of the first operation region 11. However, the present invention is not limited thereto. For example, as illustrated in FIG. 10(a), bar-shaped protrusions 11a′ having gradually changing lengths may be intermittently formed. In addition, the shape of the protrusion is not limited to the bar shape. For example, as illustrated in FIG. 10(b), spherical protrusions 11a″ or other shapes may be formed.

In the aforementioned embodiment, an example has been described, in which the operation unit 10 and the detection unit 20 are arranged in an interior part of a vehicle, such as a console, a steering wheel, or a dashboard. However, the present invention is not limited thereto. For example, the present invention may also be applied to a touch panel overlapped on a display. In this case, the first tactile sensation of the first operation region 11 and the second tactile sensations of the second operation regions 12__{U} and 12__{D} may be applied using an electronic vibration control.

Furthermore, the aforementioned embodiments may be embodied in other forms, and any one of the aforementioned embodiments is merely an example of the present invention. In addition, the technical scope of the present invention is not to be construed in a limitative sense. That is, various forms may be possible without departing from the spirit and scope of the present invention.

### REFERENCE SIGNS LIST

10 Operation unit

11 First operation region

12__{U}, 12__{D} Second operation region

20 Detection unit

30 Operation control unit

1. A touch-type input device comprising:
an operation unit having a first operation region for providing a first tactile sensation and a second operation region for providing a second tactile sensation different from the first tactile sensation, the first and second operation regions being disposed adjacent to each other;
a detection unit that detects a touch position of a pointer on the first or second operation region; and
an operation control unit that outputs a first operation signal of a degree of operation corresponding to a movement distance of the touch position when the detection unit detects a slide operation performed by changing the touch position within the first operation region; and
wherein the operation control unit outputs a second operation signal different from the first operation signal when the detection unit detects the slide operation from the first operation region to the second operation region.

2. The touch-type input device according to claim 1, wherein the operation control unit outputs, as the second operation signal, an operation signal of a degree of operation corresponding to a period of time during which the touch position stops at the second operation region.

3. The touch-type input device according to claim 1, wherein the operation control unit outputs, as the second operation signal, an operation signal of a degree of operation which corresponds to a movement distance of the touch position within the second operation region and is larger than the degree of operation corresponding to the movement distance of the touch position within the first operation region.

4. The touch-type input device according to claim 1, wherein the detection unit detects a change of the touch position with respect to a direction in which the first and second operation regions are adjacent to each other as the slide operation and does not detect a change of the touch position with respect to a direction perpendicular to the adjacent direction as the slide operation.

5. The touch-type input device according to claim 1, wherein the second operation region is disposed adjacently to each of one end and the other end of the first operation region.

6. The touch-type input device according to claim 1, wherein the operation control unit performs control such that the second operation signal is not output when the detection unit initially detects a touch of the pointer on the second operation region.

7. A method for detecting an operation using a touch-type input device provided with an operation unit having a first operation region for providing a first tactile sensation and a second operation region for providing a second tactile sensation different from the first tactile sensation, the first and second operation regions being disposed adjacent to each other; the operation detection method comprising:
a first step of detecting a touch position of a pointer on the first or second operation region using a detection unit of the touch-type input device;
a second step of outputting a first operation signal of a degree of operation corresponding to a movement distance of the touch position using an operation control unit of the touch-type input device when a slide operation in which the touch position detected by the detection unit changes within the first operation region is performed; and
a third step of outputting a second operation signal different from the first operation signal using the operation control unit when the touch position detected by the detection unit changes from the first operation region to the second operation region.

8. The operation detection method according to claim 7, wherein, in the third step, the operation control unit outputs, as the second operation signal, an operation signal of a degree of operation corresponding to a period of time during which the touch position stops at the second operation region.

9. The operation detection method according to claim 7, wherein, in the third step, the operation control unit outputs, as the second operation signal, an operation signal of a degree of operation which corresponds to a movement distance of the touch position within the second operation region and is larger than the degree of operation corresponding to the movement distance of the touch position within the first operation region.

10. The operation detection method according to claim 7, wherein, in the second step, a change of the touch position with respect to a direction in which the first and second operation regions are adjacent to each other is detected as the slide operation, and a change of the touch position with respect to a direction perpendicular to the adjacent direction is not detected as the slide operation.

11. The operation detection method according to claim 7, further comprising:
a fourth step of determining which of the first or second operation region the touch position initially detected by the detection unit belongs to and performing control such that the second operation signal is not output when the initial touch position belongs to the second operation region using the operation control unit.

12. The touch-type input device according to claim 2, wherein the detection unit detects a change of the touch position with respect to a direction in which the first and second operation regions are adjacent to each other as the slide operation and does not detect a change of the touch position with respect to a direction perpendicular to the adjacent direction as the slide operation.

13. The touch-type input device according to claim 3, wherein the detection unit detects a change of the touch position with respect to a direction in which the first and second operation regions are adjacent to each other as the slide operation and does not detect a change of the touch position with respect to a direction perpendicular to the adjacent direction as the slide operation.

14. The touch-type input device according to claim 2, wherein the second operation region is disposed adjacently to each of one end and the other end of the first operation region.

15. The touch-type input device according to claim 3, wherein the second operation region is disposed adjacently to each of one end and the other end of the first operation region.

16. The touch-type input device according to claim 2, wherein the operation control unit performs control such that the second operation signal is not output when the detection unit initially detects a touch of the pointer on the second operation region.

17. The touch-type input device according to claim 3, wherein the operation control unit performs control such that the second operation signal is not output when the detection unit initially detects a touch of the pointer on the second operation region.

18. The operation detection method according to claim 8, wherein, in the second step, a change of the touch position with respect to a direction in which the first and second operation regions are adjacent to each other is detected as the slide operation, and a change of the touch position with respect to a direction perpendicular to the adjacent direction is not detected as the slide operation.

19. The operation detection method according to claim 9, wherein, in the second step, a change of the touch position with respect to a direction in which the first and second operation regions are adjacent to each other is detected as the slide operation, and a change of the touch position with respect to a direction perpendicular to the adjacent direction is not detected as the slide operation.

20. The operation detection method according to claim 8, further comprising:
a fourth step of determining which of the first or second operation region the touch position initially detected by the detection unit belongs to and performing control such that the second operation signal is not output when the initial touch position belongs to the second operation region using the operation control unit.
